(19) United States
(12) Patent Application Publication
(10) Pub. No.: US 2026/0342289 A1
(43) Pub. Date: Oct. 29, 2026

(54) ANALOG PREDISTORTION (APD) CIRCUIT FOR POWER AMPLIFIER

(71) Applicant: Qorvo US, Inc., Greensboro, NC (US)

(72) Inventors: George Maxim, Saratoga, CA (US); Baker Scott, San Jose, CA (US); Nadim Khlat, Cugnaux (FR)

(21) Appl. No.: 19/737,129

(22) Filed: Jul. 10, 2026

Related U.S. Application Data
(63) Continuation of application No. 18/857,940, filed on Jun. 16, 2023.
(60) Provisional application No. 63/354,275, filed on Jun. 22, 2022.
(60) Provisional application No. 63/381,470, filed on Oct. 28, 2022.

(51) Int. Cl. H03F 1/32; H03F 3/24; H04B 1/04

(52) U.S. Cl. CPC H03F 1/3247; H03F 1/3282; H03F 3/245; H04B 1/0475; H04B 2001/0425

(57) ABSTRACT

An analog predistortion (APD) circuit is disclosed. In one aspect, the power amplifier is in a front-end module (FEM) of a radio frequency transceiver. An APD circuit operates within an amplifier chain to normalize the distortion of the amplifier chain. A baseband processor (BBP) performs digital predistortion (DPD) on signals being sent from the BBP to the FEM. As a result of the APD, the DPD may assume a normalized profile for the FEM, allowing for simplification of the DPD despite many possible distortions introduced by the amplifier chain.

### CROSS-REFERENCE TO RELATED APPLICATIONS

This application is a continuation of U.S. Patent Application Serial No. 18/857,940, filed Oct. 18, 2024, now U.S. Patent ___________, which is a 35 U.S.C. § 371 national stage application of International Application No. PCT/US2023/025512, filed Jun. 16, 2023, which claims the benefit of U.S. Provisional Patent Application Serial No. 63/354,275, filed Jun. 22, 2022, and U.S. Provisional Patent Application Serial No. 63/381,470, filed Oct. 28, 2022, the disclosures of each of which are hereby incorporated herein by reference in their entirety.

### BACKGROUND

### Field of the Disclosure

The technology of the disclosure relates generally to front-end modules (FEM) and particularly to predistortion applied to power amplifiers in such FEM.

### Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to increase the communication bandwidth available to supply data to the mobile communication device. This pressure has resulted in a trend to higher frequencies in the evolving cellular standards. These higher frequencies place additional pressure on the power amplifiers within the mobile communication devices to retain linear operation over a wide frequency range. Thus, there is an opportunity for innovation in helping the power amplifiers improve linear operation, particularly at high frequencies.

### SUMMARY

Aspects disclosed in the detailed description include an analog predistortion (APD) circuit for a power amplifier. In an exemplary aspect, the power amplifier is in a front-end module (FEM) of a radio frequency (RF) transceiver. An APD circuit operates within an amplifier chain to normalize the distortion profile of the amplifier chain. A baseband processor (BBP) performs digital predistortion (DPD) on signals being sent from the BBP to the FEM. As a result of the APD, the DPD may assume a normalized profile for the FEM, allowing for simplification of the DPD despite many possible distortions introduced by the amplifier chain.

In this regard, in one aspect, a power amplifier is disclosed. The power amplifier comprises a stage configured to receive a signal to be transmitted. The signal to be transmitted has DPD applied thereto before the power amplifier. The power amplifier also comprises an APD circuit configured to normalize a distortion characteristic of the stage.

In another aspect, a transceiver chain is disclosed. The transceiver chain comprises a BBP configured to apply normalized DPD to a signal. The transceiver chain also comprises a power amplifier coupled to the BBP. The power amplifier comprises a stage configured to receive the signal. The power amplifier also comprises an APD circuit configured to normalize a distortion characteristic of the stage.

### BRIEF DESCRIPTION OF THE DRAWINGS

FIG. 1 is a graph of a range of distortions for power amplifiers for different mobile terminals versus input power (Pin), highlighting the need for predistortion;

FIG. 2 is a block diagram of an exemplary analog predistortion (APD) system for a power amplifier of a mobile terminal according to an exemplary aspect of the present disclosure that tightens the range of distortions;

FIG. 3 is a graph of a tightened range of distortions for power amplifiers for different mobile terminals versus Pin after APD according to the system of FIG. 2;

FIG. 4 is a more detailed block diagram of an APD system for a power amplifier highlighting amplitude and phase predistortion options;

FIG. 5 is a block diagram of a hybrid DPD/APD system according to exemplary aspects of the present disclosure;

FIG. 6 is a block diagram illustrating how APD may be spread across stages within a power amplifier and particularly spread across a hybrid complementary metal oxide semiconductor (CMOS) stage and a bipolar material portion amplifier;

FIG. 7 is a block diagram of an alternate exemplary aspect where all adjustments are calculated in a CMOS portion of a hybrid amplifier but made in both the CMOS portion and the bipolar material portion;

FIG. 8 illustrates additional details about a look-up table that may store APD values for use by an APD circuit according to aspects of the present disclosure; and

FIG. 9 is a block diagram of a mobile terminal, which may include the hybrid predistortion system of FIGS. 2-8 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element, or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include an analog predistortion (APD) circuit for a power amplifier. In an exemplary aspect, the power amplifier is in a front-end module (FEM) of a radio frequency (RF) transceiver. An APD circuit operates within an amplifier chain to normalize the distortion profile of the amplifier chain. A baseband processor (BBP) performs digital predistortion (DPD) on signals being sent from the BBP to the FEM. As a result of the APD, the DPD may assume a normalized profile for the FEM, allowing for simplification of the DPD despite many possible distortions introduced by the amplifier chain.

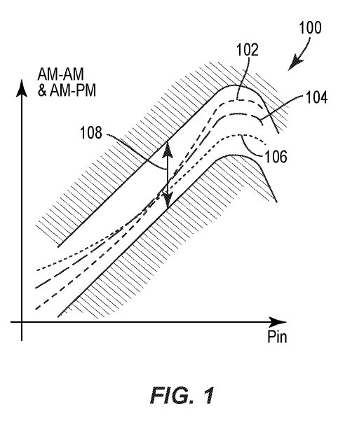

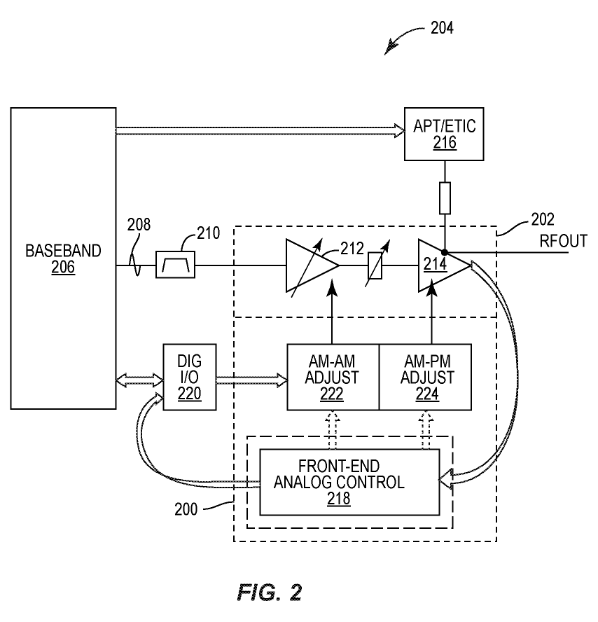

Before addressing exemplary aspects of the present disclosure, a brief overview of some of the challenges for power amplifiers in high-frequency environments, such as those of the Fifth Generation New Radio (5G-NR) cellular standards, is provided with reference to FIG. 1. A discussion of exemplary aspects of the present disclosure is provided below, beginning with reference to FIG. 2.

In general, RF transceivers rely on power amplifiers to boost signals to a desired level for wireless transmission to a remote location. To ensure that the signal transmitted is the desired frequency, amplitude, and phase, designers rely on the theory that the power amplifier will behave linearly and predictably over the frequencies and power levels of interest. For relatively low frequencies, an individual signal will likely have a fairly small bandwidth making it relatively easy to design a power amplifier that behaves linearly over the power levels of interest. As the frequencies increase, it is harder to make a power amplifier that behaves linearly over the power levels of interest. The end result is a power amplifier that distorts the signal to be transmitted. One technique that has begun to see use is predistorting the signal to be transmitted so that the predistortion cancels the distortion of the power amplifier. This predistortion is digital in nature and applied in a BBP before the signal is provided to the power amplifier. Again, at lower frequencies and across the power levels of interest, such DPD was adequate, but as power levels and frequencies have evolved, DPD techniques are challenged to achieve the desired linearity.

Adding to the challenges faced by the DPD circuitry is the fact that manufacturing processes may vary from power amplifier to power amplifier resulting in unique non-linear distortion patterns caused by the power amplifier. An entity making transceivers may need to make unique predistortion profiles for each transceiver. This uniqueness imposes additional testing time delays and increases costs associated with production of the transceivers.

By way of example, FIG. 1 is graph 100 of non-linear amplitude modulation-to-amplitude modulation (AM-AM) distortion and AM-to-phase modulation (AM-PM) distortion versus input power (Pin). A first transceiver having a first power amplifier exhibits distortion curve 102, while a second transceiver having a second power amplifier exhibits distortion curve 104, and a third transceiver having a third power amplifier exhibits distortion curve 106. The various distortion curves 102, 104, 106 create a relatively wide range 108 of possible distortion curves. Each distortion curve 102, 104, 106 would require a unique set of DPD coefficients in the BBP. As noted, this requirement is expensive and undesirable.

Exemplary aspects of the present disclosure provide a way to reduce the range of possible distortion curves such that a generic DPD circuit with a single or reduced set of DPD coefficients may be used across multiple power amplifiers and/or FEMs with power amplifiers therein. More specifically, the power amplifiers are coupled to an APD circuit that is customized to correct the unique distortion profile of the power amplifier into a normalized or generic distortion profile matching the DPD coefficients stored in the BBP.

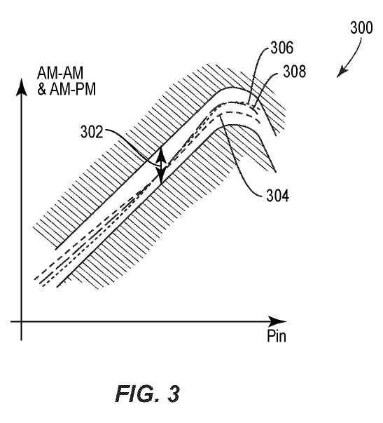

In this regard, FIG. 2 illustrates a block diagram of an exemplary APD system 200 for a power amplifier 202 of a mobile terminal 204 according to an exemplary aspect of the present disclosure that tightens the range of distortions, as better illustrated in FIG. 3. More specifically, a BBP 206 may generate a signal 208 to be transmitted after applying DPD to a signal. The signal 208 may be passed to a FEM (not explicitly shown), where the signal 208 may be filtered by a filter 210 and passed to the power amplifier 202. The power amplifier 202 may include one or more stages, such as a driver stage 212 and an output stage 214. The output stage 214 may be modulated by an average power tracking (APT) circuit or envelope tracking integrated circuit (ETIC), generically a tracking circuit 216. A detector (not shown explicitly in FIG. 2) may detect values from the output stage 214 and provide information relating thereto to a control circuit 218 that is configured to provide front-end APD including AM-AM and AM-PM spread tightening such as providing a control signal to a digital input/output (I/O) circuit 220. The digital I/O circuit 220 may provide control signals to an AM-AM adjust circuit 222 and an AM-PM adjust circuit 224. Alternatively, the control circuit 218 may communicate directly with the adjust circuits 222, 224. The AM-AM adjust circuit 222, and the AM-PM adjust circuit 224 may cause changes in bias, output levels, supply voltage, or the like to change the distortion generated in the power amplifier 202. In particular, the control circuit 218 is configured to normalize the distortion profile of the power amplifier 202 to a more generic distortion profile.

When multiple APD systems 200 are applied to multiple mobile terminals, a graph 300 may be generated showing a tightened range 302 of distortions for power amplifiers for different mobile terminals versus Pin after APD. For example, a first transceiver having a first power amplifier exhibits distortion curve 304, while a second transceiver having a second power amplifier exhibits distortion curve 306, and a third transceiver having a third power amplifier exhibits distortion curve 308. The various distortion curves 304, 306, 308 create a comparatively narrow range (i.e., tightened range 302) of possible distortion curves. Because of the tightened range 302, it may be possible to implement a BBP with only a single set of DPD coefficients while still providing desired DPD to each transceiver. This avoids the expense of customized testing and customized sets of DPD coefficients which may lower costs and make processing in the BBP more efficient.

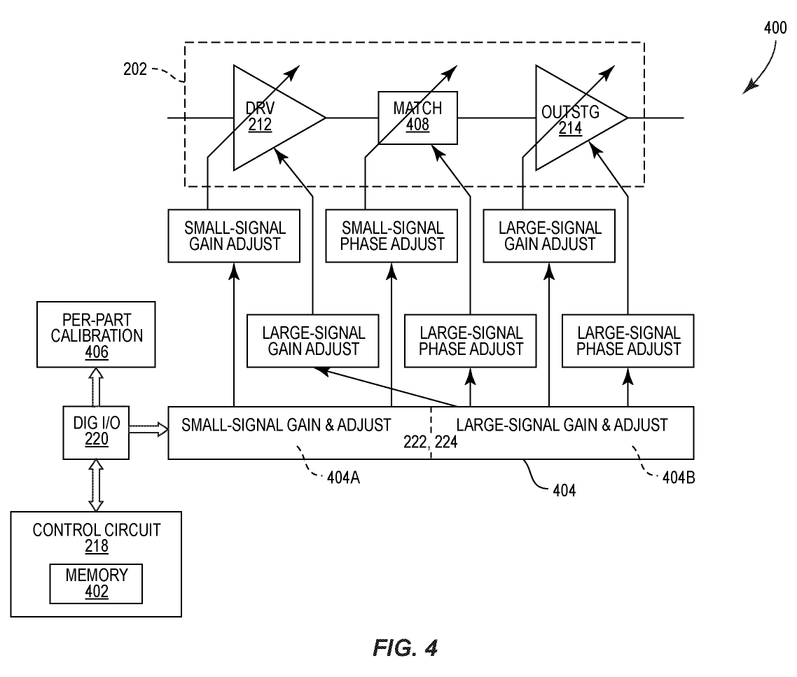

FIG. 4 is a more detailed block diagram of an APD system 400 for a power amplifier 202. It should be appreciated that multiple adjustments may be made with the APD circuit. To this end, the control circuit 218 may include a memory 402 (e.g., a read-only memory (ROM) or eFuse) that may have a look-up table (LUT) or the like that stores values for gain and phase predistortions including both small signal and large signals adjustments. These values or information relating to these values may be provided to the digital I/O circuit 220, which sends signals to an adjustment circuit 404. The adjustment circuit 404 contains the AM-AM adjust circuit 222, and the AM-PM adjust circuit 224, although as illustrated these circuits are blended into small signal gain and phase adjustment circuit 404A and a large signal gain and phase adjustment circuit 404B. The digital I/O circuit 220 may further communicate with or have information pertaining to per-part calibration values (e.g., a per-part calibration table 406), which may be used to select appropriate adjustment values. Note that the per-part calibration table 406 may be stored in the memory 402.

With continued reference to FIG. 4, the power amplifier 202 may include the driver stage 212 and the output stage 214, as well as a matching circuit 408. In an exemplary aspect, the driver stage 212 receives small signal gain adjustments and large signal gain adjustments. The driver stage 212 generally has little impact on phase distortion and accordingly, phase adjustments to the driver stage 212 may be omitted. However, other aspects may include phase adjustments to the driver stage 212 without departing from the present disclosure. The matching circuit 408 may receive small signal phase adjustments and large signal phase adjustments. The matching circuit 408 generally has little impact on the gain and accordingly, gain adjustments to the matching circuit 408 may be omitted. However, other aspects may include gain adjustments to the matching circuit 408 without departing from the present disclosure. The output stage 214 may receive large signal gain adjustments and large signal phase adjustments. The output stage 214 generally outputs large signals and accordingly omits any small signal adjustments. However, other aspects may include small signal adjustments to the output stage 214 without departing from the present disclosure. Small signal gain may be adjusted via a bias circuit (not shown) that may have a digitally controlled bias level. Setting registers can be used to change the small signal gain on a per part basis, as shown in FIG. 4. The per part basis may be effectuated through having a split bias register with common bias bits that are common for all manufactured parts and dedicated bias bits that are individually set for each front-end part.

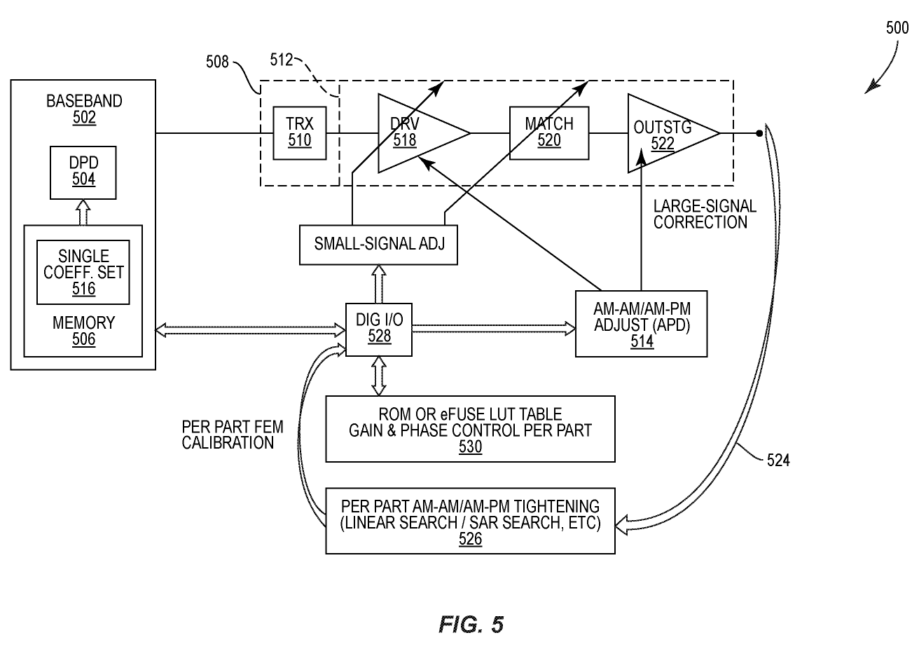

FIG. 5 is a block diagram of a hybrid DPD/APD system 500 according to exemplary aspects of the present disclosure. In particular, the system 500 includes a BBP 502 that has a DPD circuit 504 therein or associated therewith. The DPD circuit 504 may be associated with a memory 506. The BBP 502 passes a signal to be transmitted to a transceiver chain 508 that includes an intermediate and high-frequency circuit (TRX) 510 and a power amplifier 512. The intermediate and high-frequency circuit 510 may upconvert the signal from the BBP and provide some signal conditioning. Because the power amplifier 512 is associated with an APD circuit 514, the memory 506 may only store a single set of DPD coefficients 516.

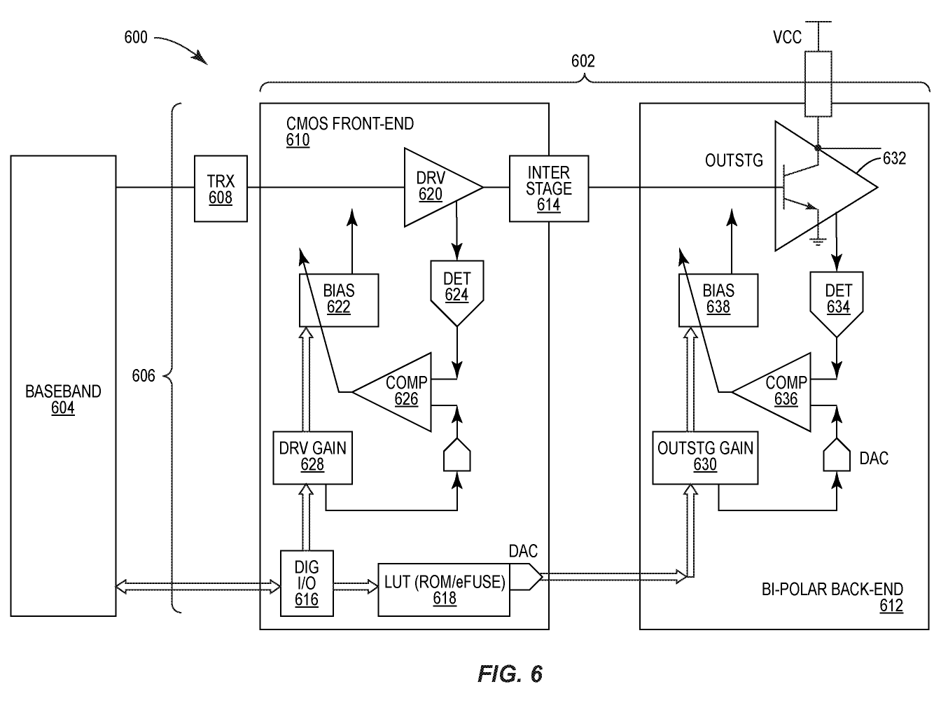

As described above, the power amplifier 512 may include a driver stage 518, a matching circuit 520, and an output stage 522. Additional stages may be present without departing from the present disclosure. Further, the power amplifier 512 may be single-ended, differential, quadrature, Doherty, barely Doherty, or the like without departing from the present disclosure. Some power amplifiers may be implemented as hybrid Bipolar-CMOS power amplifiers (e.g., gallium arsenide (GaAs)-CMOS dual technology multichip integration) having a CMOS driver (and optional pre-driver) stage 518 and bipolar output stage 522 (more detail is provided below with reference to FIG. 6). Detectors or sensors provide information about an output signal 524 to a control circuit 526, which passes information to a digital I/O circuit 528. The digital I/O circuit 528 references a memory 530 to get per-part adjustments based on the information provided by the control circuit 526. The memory 530 may be ROM, an eFUSE programmable module, and/or a ROM non-programmable module. Other memory types, such as non-volatile memory (NVM) or the like, may also be used. The digital I/O circuit 528 may cause the APD circuit 514 to then adjust the driver stage 518, the matching circuit 520, and/or the output stage 522 using small and large signal adjustments as needed.

The use of the APD circuit 514 allows the unique distortion characteristics of the power amplifier 512 to be normalized to a profile that is able to be digitally predistorted with a single set of DPD coefficients regardless of manufacturing or process variations that may exist in the power amplifier 512.

FIG. 6 is a block diagram providing more details about a system 600 having a hybrid power amplifier 602. The system has a BBP 604 analogous to the BBP 502 of FIG. 5. The system 600 has a transceiver 606 that includes a TRX circuit 608 and the hybrid power amplifier 602. The hybrid power amplifier 602 may include a CMOS front end 610 and bipolar back end 612. An interstage circuit 614 may be implemented in either the CMOS front end 610 or the bipolar back end 612. The CMOS front end 610 may include a digital I/O circuit 616, a memory 618, a driver amplifier stage 620, a bias circuit 622, and a detector 624. The digital I/O circuit 616 is analogous to the digital I/O circuit 528. The memory 618 is analogous to the memory 530. The driver amplifier stage 620 is analogous to the driver stage 518. The detector 624 provides a signal to a comparator 626 that also receives a signal from a driver gain circuit 628. Based on these signals, the comparator 626 may provide a signal to the bias circuit 622. The bias circuit 622 is also controlled by the driver gain circuit 628. By modulating the bias circuit 622, APD is applied to the driver amplifier stage 620. Note that while the driver gain circuit 628 is referred to as a “gain” circuit, it may also modify phase.

Similarly, the bipolar back end 612 may include an output gain circuit 630, an output power amplifier stage 632, a detector 634, a comparator 636, and a bias circuit 638. The digital I/O circuit 616 may communicate with the output gain circuit 630, which drives the bias circuit 638. Similarly, the bias circuit 638 may also receive information from the comparator 636. The comparator 636 compares a signal from the detector 634 and the output gain circuit 630. By modulating the output power amplifier stage 632, APD may be applied to help normalize the power amplifier 602 so that only a single set of DPD coefficients is needed. Again, while referred to as a “gain” circuit, the output gain circuit 630 may also affect the phase of the signal.

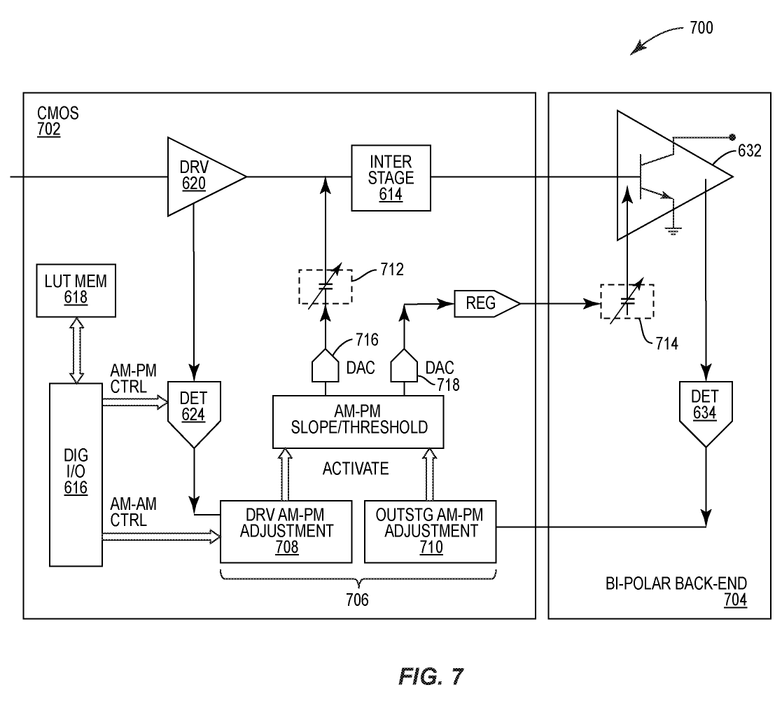

FIG. 7 is a block diagram of an alternate exemplary aspect where all adjustments are calculated in a CMOS portion of a hybrid amplifier but made in both the CMOS portion and the bipolar material portion. More specifically, a power amplifier 700 may include a CMOS portion 702 and a bipolar portion 704. Many of the elements of the power amplifier 700 are the same as the power amplifier 602 of FIG. 6 and similar parts use the same numbers. However, unlike the power amplifier 602, all the calculations are done in the CMOS portion 702, and adjustments made both in the CMOS portion 702 and the bipolar portion 704. Accordingly, the digital I/O circuit 616 may communicate with an APD circuit 706, which has a driver adjustment circuit 708 and an output stage adjustment circuit 710. The adjustment circuits 708, 710 receive signals from the detectors 624, 634 and generate signals that adjust varactors 712, 714 through DACs 716, 718 to apply APD.

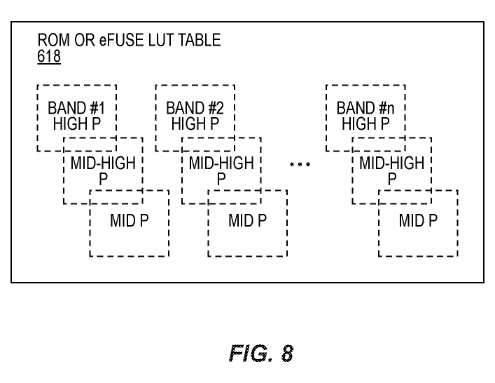

Note that the APD applied by exemplary aspects of the present disclosure may vary based on the band or channel that is in use. That is, the LUT in the memory 618 may have multiple adjustments to be made based on frequency, temperature, or the like, as better illustrated in FIG. 8, where the memory 618 has adjustments stored for different bands and different power levels.

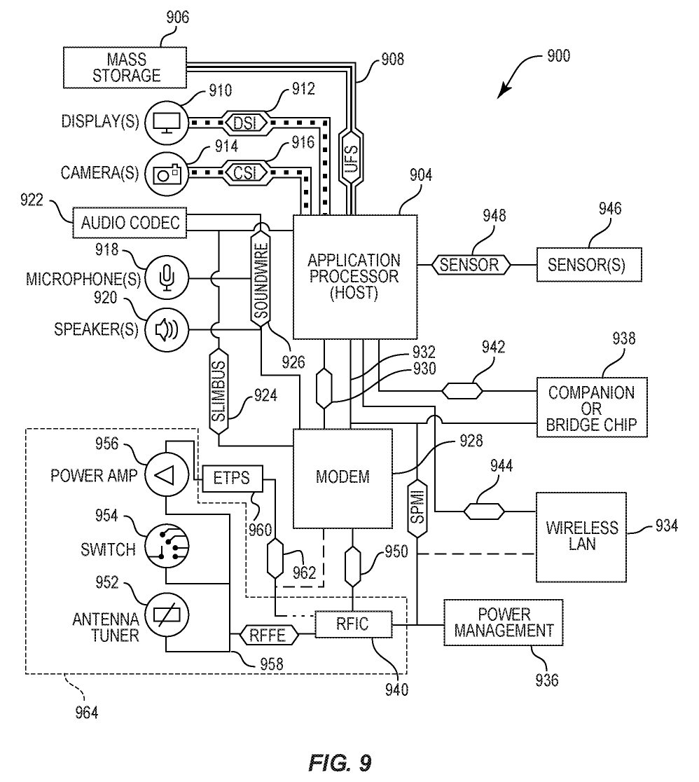

It should be appreciated that the power amplifiers of the present disclosure are frequently used in mobile terminals. In this regard, FIG. 9 is a system-level block diagram of an exemplary mobile terminal 900, such as a smartphone, mobile computing device tablet, or the like. The mobile terminal 900 includes an application processor 904 (sometimes referred to as a host) that communicates with a mass storage element 906 through a universal flash storage (UFS) bus 908. The application processor 904 may further be connected to a display 910 through a display serial interface (DSI) bus 912 and a camera 914 through a camera serial interface (CSI) bus 916. Various audio elements such as a microphone 918, a speaker 920, and an audio codec 922 may be coupled to the application processor 904 through a serial low-power interchip multimedia bus (SLIMbus) 924. Additionally, the audio elements may communicate with each other through a SOUNDWIRE bus 926. A modem 928 may also be coupled to the SLIMbus 924 and/or the SOUNDWIRE bus 926. The modem 928 may further be connected to the application processor 904 through a peripheral component interconnect (PCI) or PCI express (PCIe) bus 930 and/or a system power management interface (SPMI) bus 932.

With continued reference to FIG. 9, the SPMI bus 932 may also be coupled to a local area network (LAN or WLAN) IC (LAN IC or WLAN IC) 934, a power management integrated circuit (PMIC) 936, a companion IC (sometimes referred to as a bridge chip) 938, and a radio frequency IC (RFIC) 940. It should be appreciated that separate PCI buses 942 and 944 may also couple the application processor 904 to the companion IC 938 and the WLAN IC 934. The application processor 904 may further be connected to sensors 946 through a sensor bus 948. The modem 928 and the RFIC 940 may communicate using a bus 950.

With continued reference to FIG. 9, the RFIC 940 may couple to one or more RFFE elements, such as an antenna tuner 952, a switch 954, and a power amplifier 956 through a radio frequency front end (RFFE) bus 958. The power amplifier 956 may operate with hybrid predistortion according to exemplary aspects of the present disclosure. Additionally, the RFIC 940 may couple to an envelope tracking power supply (ETPS) 960 through a bus 962, and the ETPS 960 may communicate with the power amplifier 956. Collectively, the RFFE elements, including the RFIC 940, may be considered an RFFE system 964. It should be appreciated that the RFFE bus 958 may be formed from a clock line and a data line (not illustrated).

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A method of amplifying a signal with a power amplifier, the method comprising:
receiving a signal to be transmitted at a stage of the power amplifier, wherein the signal to be transmitted has digital predistortion (DPD) applied thereto before the power amplifier; and
normalizing a distortion characteristic of the stage with an analog predistortion (APD) circuit by applying a phase and gain adjustment to the stage such that possible distortion from the stage is changed to fall within a predefined range of possible distortion curves.

2. The method of claim 1, wherein receiving the signal to be transmitted comprises receiving the signal at a driver stage.

3. The method of claim 1, further comprising amplifying the signal to be transmitted with a second stage comprising an output stage.

4. The method of claim 3, wherein applying the phase and gain adjustment comprises also applying at least some phase and gain adjustment to the second stage.

5. The method of claim 1, wherein applying the phase and gain adjustment comprises applying small signal and large signal corrections.

6. The method of claim 3, wherein the stage comprises a complementary metal oxide semiconductor (CMOS) stage and the second stage comprises a bipolar stage.

7. The method of claim 1, further comprising coupling a varactor to the APD circuit and adjusting the stage through the varactor.

8. The method of claim 1, further comprising coupling a bias circuit to the APD circuit and the stage; and
adjusting a bias provided by the bias circuit to the stage based on information from the APD circuit.

9. A wireless communication device comprising a transceiver chain, the transceiver chain comprising:
a baseband processor (BBP) configured to apply normalized digital predistortion (DPD) to a signal; and
a power amplifier coupled to the BBP, the power amplifier comprising:
a stage configured to receive the signal; and
an analog predistortion (APD) circuit coupled to the stage and configured to normalize a distortion characteristic of the stage by applying a phase and gain adjustment to the stage such that possible distortion from the stage is changed to fall within a predefined tightened range of possible distortion curves.

10. The wireless communication device of claim 9, further comprising a matching circuit, wherein the APD circuit is configured to adjust the matching circuit to normalize the distortion characteristic.

11. The wireless communication device of claim 9, further comprising a bias circuit, wherein the APD circuit is configured to adjust the bias circuit to normalize the distortion characteristic.

12. The wireless communication device of claim 9, further comprising a memory coupled to the APD circuit.

13. The wireless communication device of claim 12, wherein the memory is configured to store APD coefficients for different communication technologies.

14. The wireless communication device of claim 12, wherein the memory is configured to store APD coefficients for different modulation signal types.

15. The wireless communication device of claim 12, wherein the power amplifier further comprises a second stage.

16. The wireless communication device of claim 15, wherein the stage comprises a complementary metal oxide semiconductor (CMOS) stage and the second stage comprises a bipolar stage.

17. The wireless communication device of claim 9, wherein the APD circuit is configured to apply small signal and large signal corrections.
